(19) United States
(12) Patent Application Publication
(10) Pub. No.: US 2013/0056845 A1
(43) Pub. Date: Mar. 7, 2013

(54) METHOD FOR FORMING AN ISOLATION TRENCH

(71) Applicants: Laurent Favennec, Villard Bonnot (FR); Cedric Perrot, Saint Martin D'Heres (FR)

(72) Inventors: Laurent Favennec, Villard Bonnot (FR); Cedric Perrot, Saint Martin D'Heres (FR)

(73) Assignee: STMICROELECTRONICS (CROLLES 2) SAS, Crolles (FR)

(21) Appl. No.: 13/607,165

(22) Filed: Sep. 7, 2012

(30) Foreign Application Priority Data
Sep. 7, 2011 (FR) 1157911

(51) Int. Cl. H01L 29/06; H01L 21/762

(52) U.S. Cl. 257/506; 438/424; 257/E21.546; 257/E29.02

(57) ABSTRACT

A method forms at least one isolation trench in a substrate having an upper surface. The method includes at least: forming, across the substrate thickness, at least one first cavity opened towards the upper surface; totally filling this first cavity with a dielectric material of a first type; forming a second cavity in an upper portion of the first cavity thus filled, said second cavity being opened towards the upper surface and having a substantially concave profile; totally filling this second cavity with a dielectric material of a second type; and leveling the free surface of the trench substantially down to the upper surface level.

### BACKGROUND

1. Technical Field

The present disclosure relates to microelectronics. It more specifically relates to an improvement relative to isolation trenches, such as commonly called STI (Shallow Trench Isolation) by those skilled in the art.

2. Description of the Related Art

Generally, active areas are currently provided in a substrate for component or electric circuit forming purposes. Further, to electrically isolate an active area from another neighboring active area, isolation areas of isolation trench type are also currently formed in this substrate.

Such trenches generally are cavities etched into the substrate and filled with a dielectric material, such as a material made of oxide, for example, silicon dioxide. A polishing then enables to remove the excess dielectric material and to level the surface of the structure.

In practice, the trench is generally filled by conformal deposition, that is, with a substantially constant thickness whatever the local orientation of the surface whereon the deposition is performed. Such a conformal deposition provides a relatively constant dielectric material thickness along the trench walls and tends, during the deposition, to close the trench by totally filling it. However, such a deposition may induce the forming of voids in the trench during the filling. To avoid the forming of such voids, the lateral walls (or sides) of the cavity, instead of being abrupt (or vertical), are slightly inclined. In other words, the wall extends from the opening to the bottom so that the opening is wider than the bottom. Indeed, with the conformal deposition techniques used to fill this cavity, one can observe that the more abrupt the wall, the higher the probability for voids to form in the trench.

Now, to increase the density of active areas in the substrate, a solution is to decrease the width of the isolation trenches. Such a decrease in the trench width results in lateral walls with strong slopes (that is, close to the vertical direction) to provide an optimal electric isolation, and especially towards the bottom of the trench.

Different techniques for filling such thin trenches have been developed. Such techniques decrease the probability of forming of voids deep inside the trench, but increase the probability of forming of voids at the trench surface. Thereby, with such thin trench filling techniques, the voids tend to form more at the trench surface than in depth. In practice, it is possible to detect shallow voids with the methods and equipment for automatically inspecting integrated circuit wafers currently used in microelectronics, and thus to measure the surface density (defects/cm ²) of voids close to the surface.

Now, the presence of voids at the trench surface may have disadvantages. For example, in the case of the forming of a transistor in a silicon-based substrate, the forming of gates involves a step of deposition of a polysilicon layer on the silicon layer containing such isolation trenches, followed by a step of etching of the polysilicon layer to form the desired patterns. In particular, during the deposition step, polysilicon ends up in some of the voids present at the trench surface. The presence of polysilicon in the trench especially generates short-circuits and induces an efficiency loss.

### BRIEF SUMMARY

One embodiment of the present disclosure is a method for forming isolation trenches, for example, STI-type isolation trenches, wherein the probability of forming of voids in the trench is decreased, and especially in an upper portion of the trench.

One embodiment of the present disclosure provides a method for forming at least one isolation trench in a substrate having an upper surface, comprising at least:

the forming, across the substrate thickness, of at least one first cavity opened towards the upper surface;

the total filling of this first cavity with a first dielectric material;

the forming, by chemical-mechanical polishing, of a second cavity in an upper portion of the first cavity thus filled, said second cavity being opened towards the upper surface and having a substantially concave profile;

the total filling of this second cavity with a second dielectric material; and

the leveling of the free surface of the trench substantially down to the upper surface level.

The chemical-mechanical polishing (CMP) especially enables to shape the second cavity with a profile promoting the deposition of dielectric material, that is, a void-free deposition. In particular, the chemical-mechanical polishing enables to form a substantially concave profile, the walls of this second cavity thus advantageously having a smoother slope (less abrupt) than the walls of the lower portion of the first cavity.

In other words, the chemical-mechanical step does not remove the entire volume of first dielectric material contained in the upper portion of the first cavity, but rather digs the second concave cavity in the volume of dielectric material contained in the upper portion of the first cavity. Thus, unlike a chemical etching, for example, an anisotropic etching, which would totally remove the volume of first dielectric material contained in the upper portion of the first cavity, advantageously after the chemical-mechanical polishing step, the walls of the upper portion of the first cavity are still covered with first dielectric material.

According to an embodiment, the lateral walls of the upper portion of the first cavity may be substantially vertical and the lateral walls of a lower portion of the first cavity may be inclined with respect to the lateral walls of the upper portion, the opening of the first cavity being wider than the bottom of the first cavity.

In practice,

the first cavity may be formed by etching of the substrate;

the first cavity may be filled by a deposition of chemical vapor deposition type;

the second cavity may be filled by a deposition of chemical vapor deposition type;

the free surface of the trench may be leveled by a chemical-mechanical polishing;

the substrate may be formed of a stack of layers comprising at least one insulating layer interposed between a stop layer and an active layer;

the upper portion may be delimited by the stop layer and the insulating layer, and the lower portion may be delimited by the active layer; and

the bottom of the second cavity may be above the active layer.

### BRIEF DESCRIPTION OF THE SEVERAL VIEWS OF THE DRAWINGS

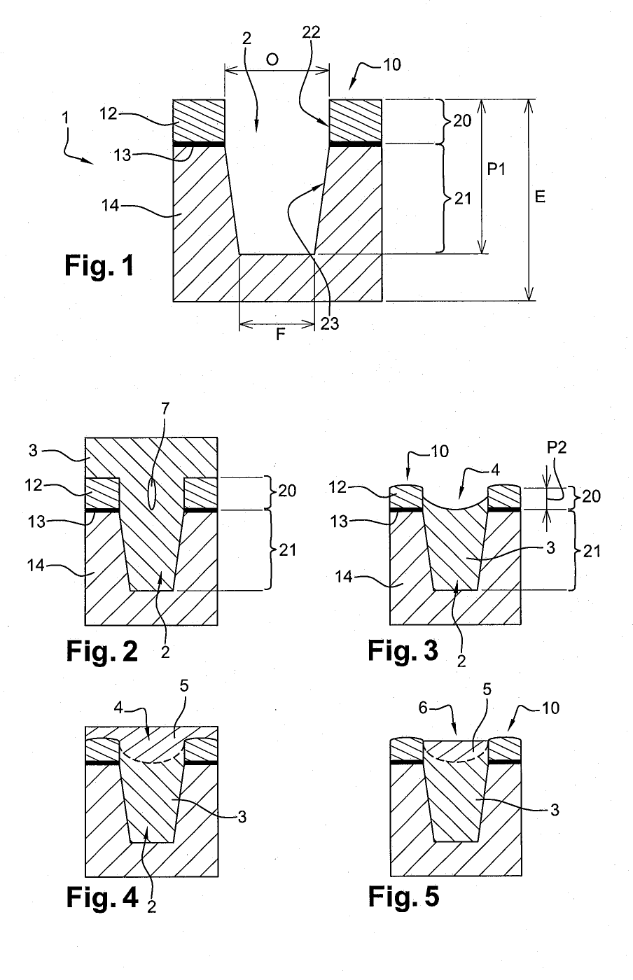

The foregoing and other features and advantages of the present disclosure will be discussed in detail in the following non-limiting description of specific embodiments in connection with accompanying drawings, FIGS. 1 to 5 being simplified cross-section views illustrating steps of a method for forming an isolation trench in a substrate according to an embodiment of the present disclosure.

### DETAILED DESCRIPTION

The method for forming an isolation trench in a substrate especially comprises digging into an upper portion a first cavity totally filled with a dielectric material, to remove the possible voids present in this upper portion. The second cavity thus formed preferably has a geometry capable of limiting, or even eliminating, the occurrence of voids on deposition of another dielectric material in this second cavity. FIGS. 1 to 5 illustrate the steps of the method for forming such an isolation trench in a substrate 1 having an upper surface 10.

This method first comprises:

the forming (FIG. 1), across the thickness E of substrate 1, of a first cavity 2 opened towards upper surface 10; and

the total filling (FIG. 2) of first cavity 2 with a first dielectric material 3.

Preferably, first cavity 2 has a geometry suitable for a conformal deposition of the first dielectric material 3 without the forming of voids in a lower portion 21 of this first cavity 2 and with the forming of voids in an upper portion 20 of first cavity 2. In practice, the geometry of first cavity 2 is selected so that the probability of forming (or of appearing) voids in upper portion 20 is greater than the probability of forming (or of appearing) voids in lower portion 21. Thus, advantageously, lower portion 21 is free of voids.

In other words, the forming of voids in lower portion 21 of the first cavity is limited with respect to the forming of voids in upper portion 20 of the first cavity on filling of this first cavity with the first dielectric material.

For example, as illustrated in FIG. 1, lateral walls 22 of upper portion 20 are substantially vertical (or abrupt), and lateral walls 23 of lower portion 21 have an inclination such that opening O of first cavity 2 is wider than its bottom F. Indeed, the higher the slope of the trench wall, the greater the probability of occurrence of voids. Preferably, lateral walls 22 of upper portion 20 are substantially perpendicular to upper surface 10. In other words, in this example, upper portion 20 has a substantially rectangular profile and lower portion 21 has a substantially trapezoidal profile.

The method for forming an isolation trench then comprises:

the forming (FIG. 3) of a second cavity 4 in the filled first cavity 2, this second cavity 4 being also opened towards upper surface 10; and

the total filling (FIG. 4) of second cavity 4 with a second dielectric material 5.

In other words, second cavity 4 is dug into the volume of first dielectric material 3 contained in first cavity 2. Second cavity 4 is dug down to a depth enabling to remove most voids (schematically shown by element 7 in FIG. 2) which have formed in upper portion 20 of first cavity 2 once filled.

This second cavity 4 preferably has a geometry suitable for a deposition of the second dielectric material 5 with no forming of voids. In practice, the geometry of second cavity 4 is selected so that the probability of forming of voids capable of forming in second cavity 4 during the filling is smaller than or equal to the probability of forming of voids present in lower portion 21.

Advantageously, second cavity 4 has sides with a very little inclination with respect to upper surface 10, and an opening-to-depth ratio very favorable to a deposition with very little void formation if any. For example, as illustrated in FIG. 3, second cavity 4 preferably has a substantially concave profile. Due to this geometry, the walls of second cavity 4 have a favorable inclination to limit the forming of voids during the filling.

After the filling of this second cavity 4, free surface 6 of the trench thus formed is leveled (FIG. 5) substantially all the way to the level of upper surface 10.

The isolation trench thus formed thus comprises two dielectric materials deposited in a cavity. The first and second dielectric materials 3 and 5 may be identical or different.

For example, the conductivity or the mobility of the carriers of a material may be modified according to the mechanical stress applied to the material. It is thus possible to provide a second dielectric material that does not have the same chemical properties as the first dielectric material, so that the thermal modifications undergone by the structure during the forming of a component, for example, an anneal, induce a different mechanical stress between the upper portion and the lower portion of the trench.

The first and second dielectric materials 3 and 5 may be based on oxide, for example, on silicon dioxide, or again of silicon oxycarbide or oxynitride (SiOC, SiON).

First cavity 2 formed in substrate 1 preferably has a maximum depth P1 smaller than or equal to 400 nm, especially approximately ranging from 200 nm to 600 nm, for example 300 nm.

Second cavity 4 formed in upper portion 20 preferably has a maximum depth P2 smaller than or equal to 80 nm, especially approximately ranging from 20 nm to 100 nm, for example 50 nm.

Depths P1 and P2 are especially defined with respect to a reference plane formed by upper surface 10.

The ratio of maximum depth P1 of first cavity 2 to the largest width of bottom F of first cavity 2 is preferably smaller than or equal to 4, and especially approximately ranging from 3 to 5, for example, 4.

The ratio of the greatest width of opening O of first cavity 2 to the greatest width of bottom F of the first cavity is preferably smaller than or equal to 1.5, especially approximately ranging from 1 to 2, for example, 1.5.

The ratio of the greatest width of the opening of second cavity 4 to maximum depth P2 of this second cavity is preferably greater than or equal to 1, and especially approximately ranging from 0.5 to 2, for example 1.

In an embodiment, the different steps of the method may be implemented with the following techniques.

First cavity 2 may especially be formed by etching of substrate 1. The implemented etch technique may for example be a plasma etching (of RIE type, “Reactive Ion Etching”) using halogenated precursors containing at least one of atoms Cl, Br and/or F.

First and second cavities 2, 4 may be filled by chemical vapor deposition (CVD). For example, a low-pressure chemical vapor deposition (LPCVD) or a sub-atmospheric pressure chemical vapor deposition (SACVD), or any deposition technique adapted to the filling of this first cavity 2 with the dielectric material of the first type 3 may be used.

Advantageously, this filling may be carried out by the implementation of an SACVD method at high temperature (temperature between 480° C. and 550° C.) commonly used in microelectronics for the filling of the STI trenches. It may in particular be a method commonly called HARP (“High Aspect Ratio Process”) by those skilled in the art. This technique provides a highly conformal deposition.

Second cavity 4 may especially be formed by chemical-mechanical polishing (CMP). This type of polishing especially enables to level and to smooth reliefs by combining a chemical etching and a mechanical polishing. The structural features of the second cavity may especially be obtained by adjusting polishing parameters such as the rotation speed, the applied force, and the material and the shape of the polishing pad. As an example, the rotation speed may range between 40 and 80 revolutions per minute, the applied pressure may range between 2 and 5 Psi, the hardness of the polishing pad may be selected between 15 and 20 MPa; and the polishing selectivity between oxide and nitride may be selected between 10 and 100.

Finally, the trench surface may also be leveled by the above-described polishing method. This polishing step especially enables to level and to smooth the free surface of the trench by removing the excess dielectric material residue. The polishing parameters are of course adjusted to decrease height variations between free surface 6 of the trench and upper surface 10 of the substrate.

When the above polishing method is implemented, it is preferable to well define the area to be polished to avoid deteriorating the areas located around the trench. For example, it is possible to provide a stop layer in the substrate, this stop layer especially having the function of protecting the areas located around the trench during the polishing.

In an advantageous embodiment, substrate 1 may thus be formed of a stack of layers comprising an insulating layer 13 interposed between a stop layer 12 and an active layer 14 (FIG. 1). The free surface of stop layer 12 forms upper surface 10 of substrate 1.

Stop layer 12 is preferably based on nitride, for example, on silicon nitride, and may have a thickness smaller than or equal to 80 nm, especially approximately ranging from 40 nm to 120 nm, for example, 70 nm. This stop layer may also be based on a material which resists the implemented polishing method.

Insulating layer 13 is preferably based on oxide, for example, on silicon dioxide, and may have a thickness smaller than or equal to 8 nm, especially approximately ranging from 3 nm to 11 nm, for example, 50 nm.

In this embodiment, first cavity 2 thoroughly crosses stop layer 12 and insulating layer 13 and partially crosses active layer 14. Upper portion 20 of first cavity 2 is adjacent to stop layer 12 and to insulating layer 13, and lower portion 21 of first cavity 2 is adjacent to active layer 14. The thickness of upper portion 20 is for example substantially equal to the sum of the thicknesses of stop layer 12 and of insulating layer 13. Preferably, second cavity 4 is dug through stop layer 12 and insulating layer 13, the etching substantially stopping at the level of active layer 14.

The provided method for forming an STI-type trench especially comprises a first phase providing a lower probability of forming of voids in the lower portion of the first cavity than the probability of forming of voids in the upper portion of this first cavity. During a second phase, a second cavity is dug into upper portion to remove the voids which have formed therein. The geometry of this second cavity is suitable for a limitation of the forming of voids during its filling. In the end, the probability of forming of deep voids and the probability of forming of surface voids at the trench surface are decreased.

Of course, the present disclosure is likely to have various alterations, modifications, and improvements which will readily occur to those skilled in the art. Such alterations, modifications, and improvements are intended to be part of this disclosure, and are intended to be within the spirit and the scope of the present disclosure. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming an isolation trench in a substrate having an upper surface, the forming including:
forming, across a thickness of the substrate, a first cavity opened towards the upper surface;
totally filling the first cavity with a first dielectric material;
forming, by chemical-mechanical polishing, a second cavity in an upper portion of the first cavity after totally filling the first cavity, said second cavity being opened towards the upper surface and having a substantially concave profile;
totally filling the second cavity with a second dielectric material; and
leveling a free surface of the second dielectric material substantially down to the upper surface of the substrate.

2. The method of claim 1, wherein the upper portion of the first cavity has lateral walls that are substantially vertical and a lower portion of the first cavity has lateral walls that are inclined with respect to the lateral walls of the upper portion, the first cavity having an opening that is wider than a bottom of the first cavity.

3. The method of any of claims 1, wherein forming the first cavity includes etching the substrate.

4. The method of claim 1, wherein totally filling the first cavity includes depositing the first dielectric material using chemical vapor deposition.

5. The method of claim 1, wherein totally filling the second cavity includes depositing the first dielectric material using chemical vapor deposition.

6. The method of claim 1, wherein the leveling includes leveling the free surface by chemical-mechanical polishing.

7. The method of claim 1, comprising forming the substrate of a stack of layers that includes an active layer, a stop layer, and an insulating layer interposed between the stop layer and the active layer.

8. The method of claim 7, wherein the upper portion is delimited by the stop layer and the insulating layer, and the lower portion is delimited by the active layer.

9. The method of claim 7, wherein the second cavity has a bottom that is above the active layer.

10. The method of claim 1, wherein the first and second dielectric materials are of the same dielectric material type.

11. An integrated circuit structure, comprising:
a substrate having an upper surface; and
an isolation trench in the substrate, the isolation trench including:
a first dielectric material positioned in a lower portion of a cavity in the substrate, the cavity extending into the substrate from the upper surface, the first dielectric material covering side walls of the cavity and having a substantially concave upper surface;
a second dielectric material positioned in an upper portion of the cavity and on the first dielectric material, the second dielectric material having a substantially convex lower surface mated with the upper surface of the first dielectric material.

12. The integrated circuit structure of claim 11, wherein the upper portion of the cavity has lateral walls that are substantially vertical and the lower portion of the cavity has lateral walls that are inclined with respect to the lateral walls of the upper portion, the cavity having an opening that is wider than a bottom of the cavity.

13. The integrated circuit structure of claim 11, wherein the second dielectric material has an upper surface substantially aligned with the upper surface of the substrate.

14. The integrated circuit structure of claim 11, wherein the substrate includes a stack of layers that includes an active layer, a stop layer, and an insulating layer interposed between the stop layer and the active layer.

15. The integrated circuit structure of claim 14, wherein the upper portion is delimited by the stop layer and the insulating layer, and the lower portion is delimited by the active layer.

16. The integrated circuit structure of claim 14, wherein the lower surface of the second dielectric material is above the active layer.

17. The integrated circuit structure of claim 11, wherein the first and second dielectric materials are of the same dielectric material type.

18. A method of forming an integrated circuit structure, comprising:
forming a substrate having an upper surface; and
forming an isolation trench in the substrate, wherein forming the isolation trench includes:
forming a first dielectric material positioned in a lower portion of a cavity in the substrate, the cavity extending into the substrate from the upper surface, the first dielectric material covering side walls of the cavity and having a substantially concave upper surface;
forming a second dielectric material positioned in an upper portion of the cavity and on the first dielectric material, the second dielectric material having a substantially convex lower surface mated with the upper surface of the first dielectric material.

19. The method of claim 18, wherein the upper portion of the cavity has lateral walls that are substantially vertical and the lower portion of the cavity has lateral walls that are inclined with respect to the lateral walls of the upper portion, the cavity having an opening that is wider than a bottom of the cavity.

20. The method of claim 18, wherein the first and second dielectric materials are of the same dielectric material type.
